(19) United States
(12) Patent Application Publication
(10) Pub. No.: US 2003/0223189 A1
(43) Pub. Date: Dec. 4, 2003

(54) Notebook computer with low surface temperature

(76) Inventor: Yung-Shun Chen, Luju Shiang (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 10/264,678

(22) Filed: Oct. 4, 2002

(30) Foreign Application Priority Data
May 31, 2002 (TW) 91208029

(51) Int. Cl. G06F 1/16; H05K 5/00; H05K 7/00

(52) U.S. Cl. 361/683

(57) ABSTRACT

A notebook computer with a low surface temperature. The notebook computer comprises a housing, a main board, a frame, and a hard drive. The housing includes a cover, and the main board is disposed in the housing. The frame, disposed on the main board, includes two supports and a connecting portion connecting the supports. The hard drive is disposed in the frame.

### BACKGROUND OF THE INVENTION

### FIELD OF THE INVENTION

The invention relates to a notebook computer; in particular, a notebook computer with a low surface temperature.

### DESCRIPTION OF THE RELATED ART

Since a notebook computer itself is only provided with limited functions, it must usually connect to other peripheral devices to expand its functions. For example, the notebook computer may be placed on a port replicator and connected with the port replicator. However, when the rear portion of the is notebook computer is placed on the port replicator, the notebook computer is inclined relative to a desk for the port replicator disposed thereon. Thus, extractable devices, such as CD ROM or DVD, cannot be positioned in the front portion of the notebook computer so as to be prevented from colliding with the desk during operation. As a result, the extractable devices can only be positioned on the sides. Furthermore, to provide sufficient area for a main board of the notebook computer, a hard drive of the notebook computer must be disposed on the main board and located under a cover.

FIG. 1a, FIG. 1b, and FIG. 1c are schematic views of a conventional notebook computer 100. The conventional notebook computer 100 comprises a main portion 110 and a display portion 120. As shown in FIG. 1b and FIG. 1c, the main portion 110 includes a cover 111, a frame 112, a hard drive 113, a main board 114, and a base 115. The hard drive 113, the main board 114, and the frame 112 are located between the cover 111 and the base 115. The main board 114 is disposed on the base 115, the frame 112 is disposed on the main board 114, and the hard drive 113 is disposed in the frame 112.

The frame 112 is of aluminum, an excellent thermally conductive material. Thus, the heat, generated by a processor (not shown) and a chipset 116 located on the main board 114, is easily transferred to the cover 111 via the frame 112. As a result, the temperature of the outer surface of the cover 111 increases due to heat transferred from the frame 112, creating user discomfort.

### SUMMARY OF THE INVENTION

In order to address the disadvantages of the aforementioned notebook computer, the invention provides a notebook computer with a low surface temperature.

Accordingly, the invention provides a notebook computer with a low surface temperature. The notebook computer comprises a housing, a main board, a frame, and a hard drive. The housing includes a cover, and the main board is disposed in the housing. The frame, disposed on the main board, includes two supports and a connecting portion connecting the supports. A space is formed between the supports. The hard drive is disposed in the frame.

In another preferred embodiment, the frame is of thermally insulative material, such as plastic.

In another preferred embodiment, the frame defines a plurality of through holes on the supports and the connecting portion.

In another preferred embodiment, a gap is formed between the top of the frame and the cover, and ranges from 0.5 mm to 1 mm. That is, the cover is set with a predetermined distance from the top of the frame.

Furthermore, this invention provides another notebook computer. The notebook computer comprises a housing, a main board, a heat-isolation member, and a hard drive. The housing includes a cover, and the main board is disposed in the housing. The heat-isolation member is disposed on the main board. The hard drive is disposed on the main board via the heat-isolation member so that the heat-isolation member is located between the hard drive and the main board. A gap is formed between the hard drive and the cover. That is, the cover is set with a predetermined distance from the top of the hard drive.

### BRIEF DESCRIPTION OF THE DRAWINGS

The invention is hereinafter described in detail with reference to the accompanying drawings in which:

FIG. 1a is a schematic view of a conventional notebook computer;

FIG. 1b is a partial exploded schematic view showing a main portion in FIG. 1a;

FIG. 1c is a partial cross section showing the main portion in FIG. 1a;

FIG. 2a is a schematic view of a notebook computer as disclosed in this invention;

FIG. 2b is a partial exploded schematic view showing a main portion of a notebook computer in a first embodiment;

FIG. 2c is a partial cross section showing the main portion in FIG. 2b;

FIG. 2d is a schematic view of a frame in FIG. 2b;

FIG. 3a is a partial exploded schematic view showing a main portion of a notebook computer in a second embodiment;

FIG. 3b is a partial cross section showing the main portion in FIG. 3a.

### DETAILED DESCRIPTION OF THE INVENTION

### First Embodiment

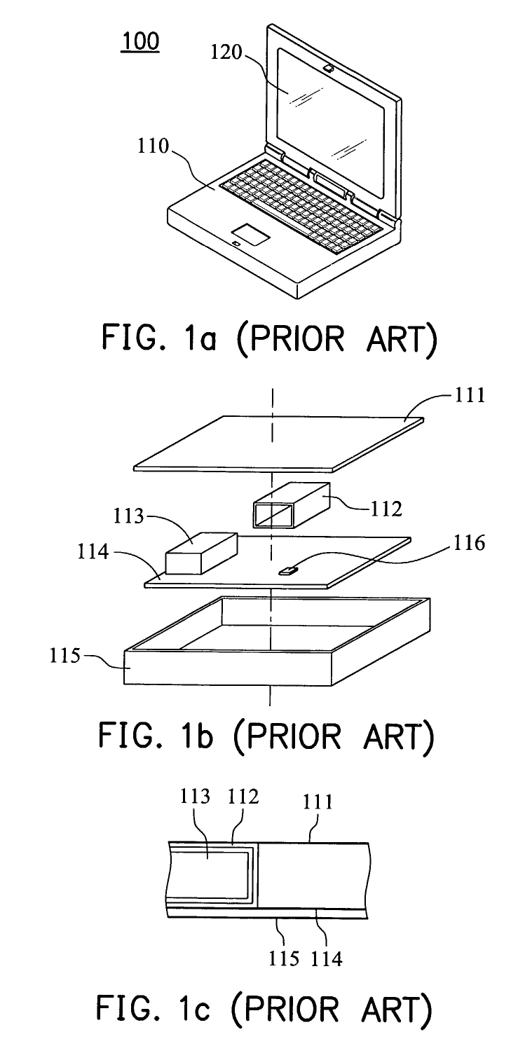

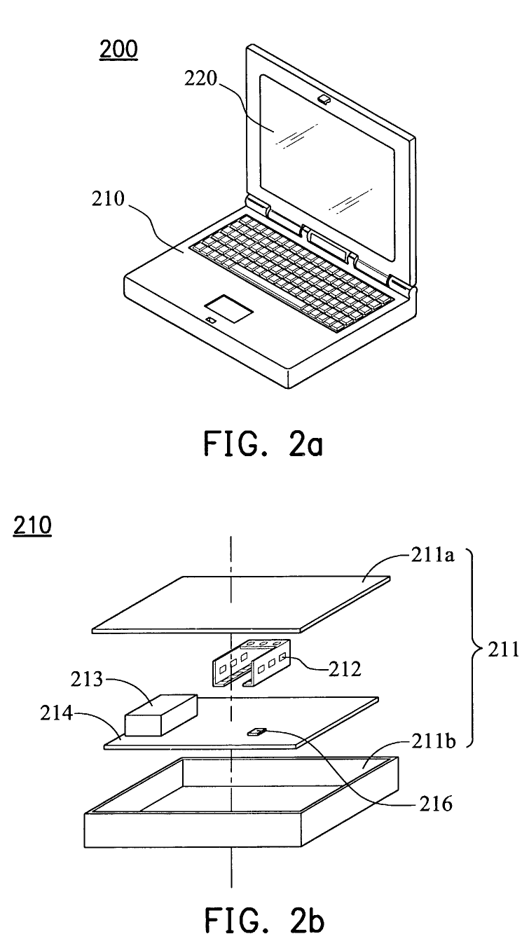

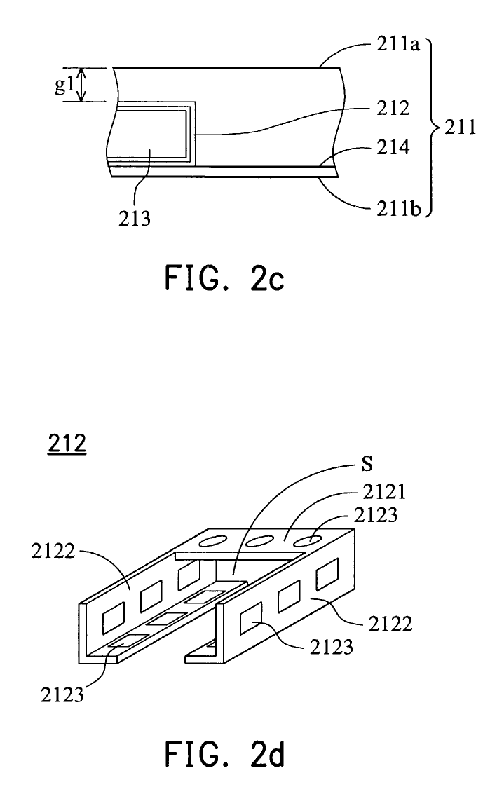

Referring to FIG. 2a, FIG. 2b, and FIG. 2c, a basic structure of a notebook computer 200 of a first embodiment as disclosed in this invention is the same as that of the conventional notebook computer 100 as shown in FIG. 1a. The notebook computer 200 comprises a main portion 210 and a display portion 220.

As shown in FIG. 2b and FIG. 2c, the main portion 210 comprises a housing 211, a main board 214, a frame 212, and a hard drive 213. The housing 211 is used as a body of the main portion 210, and includes a cover 211a and a base 211b.

The main board 214 is disposed on the base 211b of the housing 211 and located in the housing 211, and includes a plurality of chipsets 216 disposed thereon. It is noted that only one chipset 216 is shown in FIG. 2b.

Referring to FIG. 2d, the frame 212 includes two supports 2122 and a connecting portion 2121 connecting the supports 2122. The supports 2122 support the hard drive 213, and define a space S between them. The frame 212 defines a plurality of through holes 2123 on its connecting portion 2121 and supports 2122. The through holes 2123 may be circular or rectangular so as to retard or delay heat conduction through the frame. When the number of the through holes 2123 is increased, the heat conduction through the frame of the frame 212 is retarded more as long as the structural strength of the frame 212 is not affected. Furthermore, as shown in FIG. 2c, the frame 212 is disposed on the main board 214 in a manner such that a gap g1 is formed between the top of the frame 212 and the cover 211a of the housing 211. That is, the cover 211a is set with a predetermined distance g1 from the top of the frame 212. Thus, the heat, generated by the chipset 216 and a processor (not shown) on the main board 214, can be prevented from transferring to the cover 211a of the housing 211 via the frame 212.

Furthermore, since there is a space S formed between the supports 2122, heat conduction through the frame 212 can be retarded.

In addition, the gap g1 can prevent more heat conduction, and the distance g1 is at least 0.5 mm.

It is understood that the frame 212 may be of thermally insulative material such as plastic so as to actually prevent the heat, generated by the chipset 216 and others on the main board 214, from transferring to the cover 211a of the housing 211 via the frame 212. It is also understood that the thermally insulative material is a material with a low heat transfer coefficient.

However, for structural strength, the frame 212 may be of stainless steel. Thus, the hard drive 213, disposed in the frame 212, is prevented from vibrating with external shock.

Furthermore, when the frame 212 is of stainless steel, it does not only prevent vibrating, but also assists in dissipating ESD or EMI.

During operation, the temperature of the outer surface of the cover 211a of the notebook computer 200 is higher than the ambient temperature of about 15° C. Similarly, the temperature of the outer surface of the cover 111 of the conventional notebook computer 100 is higher than the ambient temperature of about 20° C. during operation. Thus, user discomfort with the notebook computer 200 as disclosed in this invention is reduced.

Since the frame is of thermally insulative material, the frame can retard the heat transfer, and the temperature of the outer surface of the cover remains at an acceptable level.

In addition, since there is a gap/distance between the frame and the housing, a fan in the notebook computer can easily generate air flow to carry heat from the frame.

### Second Embodiment

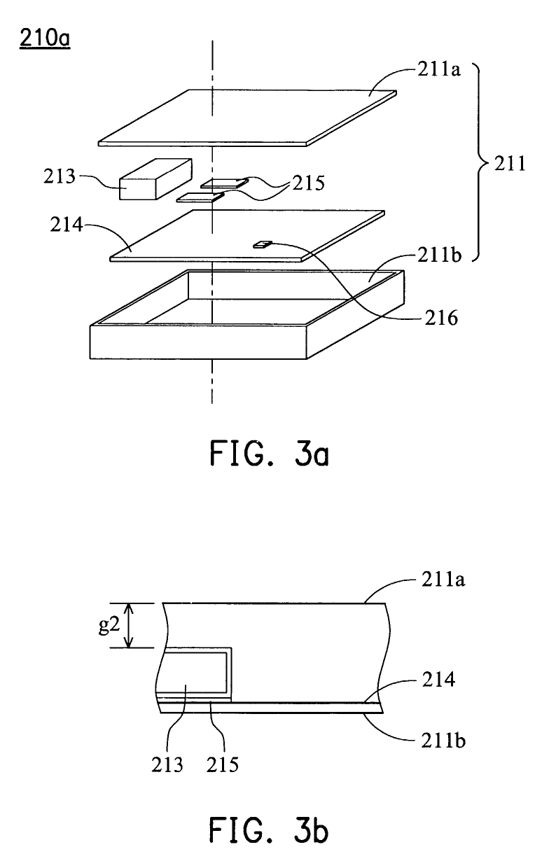

A basic structure of a notebook computer of a second embodiment as disclosed in this invention is the same as that of the notebook computer of the first embodiment as disclosed in this invention. Referring to FIG. 3a, and FIG. 3b, a main portion 210 of the notebook computer of the second embodiment comprises a housing 211, a main board 214, two heat-isolation members 215, and a hard drive 213. The main board 214 is disposed in the housing 211.

The difference between the second embodiment and the first embodiment is that the heat-isolation members 215 in the second embodiment replace the frame 212 in the first embodiment. The heat-isolation members 215 are disposed on the main board 214, and are located under the hard drive 213. The heat-isolation members 215 may be disposed on the bottom portion of the hard drive 213 near both sides. Thus, the hard drive 213 is disposed on the main board 214 via the heat-isolation members 215. It is noted that a gap g2 is formed between the hard drive 213 and the cover 211a of the housing 211 as shown in FIG. 3b . That is, the cover 211a is set with a predetermined distance g2 from the top of the hard drive 213.

It is understood that the heat-isolation members 215 may be of thermally insulative material, such as plastic.

Furthermore, since there is a gap/distance g2 formed between the hard drive 213 and the cover 211a, the heat, generated by the chipset 216 and others on the main board 214, can be prevented from directly transferring to the cover 211a of the housing 211. Since the gap/distance g2 can prevent the heat conduction through the frame more as it becomes larger it is made at least 0.5 mm, and may range from 0.5 mm to 1 mm.

During operation, the temperature of the outer surface of the cover 211a of this embodiment is higher than the ambient temperature of about 14.9° C. Similarly, the temperature of the outer surface of the cover 111 of the conventional notebook computer 100 is higher than the ambient temperature of about 20° C. during operation, again reducing user discomfort.

Since the heat-isolation members are disposed between the hard drive and the main board, the heat-isolation members can retard the heat transfer, and the temperature of the outer surface of the cover remains at an acceptable level.

While the invention has been particularly shown and described with reference to a preferred embodiment, it will be readily appreciated by those of ordinary skill in the art that various changes and modifications may be made without departing from the spirit and scope of the invention. It is intended that the claims be interpreted to cover the disclosed embodiment, those alternatives which have been discussed above, and all equivalents thereto.

What is claimed is:

1. A notebook computer comprising a housing, a main board disposed in the housing, and a hard drive disposed in the housing over the main board, comprising:
a frame for receiving the hard drive, disposed on the main board, including two supporting portions and a connecting portion connecting the supporting portions.

2. The notebook computer as claimed in claim 1, wherein the frame is made of thermally insulative material.

3. The notebook computer as claimed in claim 2, wherein the frame is made of plastic.

4. The notebook computer as claimed in claim 1, wherein a plurality of through parts locate on the supporting portions and the connecting portion.

5. The notebook computer as claimed in claim 1, wherein a top of the housing is set with a predetermined distance from a top of the frame.

6. The notebook computer as claimed in claim 1, wherein the frame is made of stainless steel.

7. A notebook computer comprising a housing with a cover, a main board disposed in the housing, and a hard drive disposed in the housing over the main board, comprising:
a heat-isolation member disposed between the main board and the hard drive,
wherein the cover is set with a predetermined distance from the top of the hard drive.

8. The notebook computer as claimed in claim 7, wherein the heat-isolation member is made of thermally insulative material.

9. The notebook computer as claimed in claim 8, wherein the heat-isolation member is made of plastic.

10. The notebook computer as claimed in claim 7, wherein the heat-isolation member is located under the hard drive near a side surface of the hard drive.
